(19) United States
(12) Patent Application Publication
(10) Pub. No.: US 2026/0038777 A1
(43) Pub. Date: Feb. 5, 2026

(54) INFORMATION PROCESSING APPARATUS, COMPUTER-READABLE MEDIUM, AND INFORMATION PROCESSING METHOD

(71) Applicant: Tokyo Electron Limited, Tokyo (JP)

(72) Inventor: Shinsuke OKA, Miyagi (JP)

(73) Assignee: Tokyo Electron Limited, Tokyo (JP)

(21) Appl. No.: 19/353,643

(22) Filed: Oct. 9, 2025

Related U.S. Application Data
(63) Continuation of application No. PCT/JP2024/014516, filed on Apr. 10, 2024.

(30) Foreign Application Priority Data
Apr. 17, 2023 (JP) 2023-067341

(51) Int. Cl. H01J 37/32

(52) U.S. Cl. CPC H01J 37/32724; H01J 37/32091; H01J 37/32146; H01J 37/32183; H01J 37/32449; H01J 2237/182; H01J 2237/2001; H01J 2237/2007

(57) ABSTRACT

A process includes acquiring temperature data indicating a temperature of a substrate placed on the substrate stage and temperature data indicating a temperature of the coolant, calculating, based on the acquired temperature data indicating the temperature of the substrate and the acquired temperature data indicating the temperature of the coolant, a thermal resistance of a heat conduction site on a heat transfer path from the substrate to the coolant, and calculating a heat flux to the substrate for each of a plurality of steps of a process recipe defining a substrate processing to be performed on the substrate. The process also includes calculating, based on the calculated thermal resistance and the calculated heat flux, an offset value to be added to a set temperature of the coolant for each of the steps.

### CROSS-REFERENCE TO RELATED APPLICATIONS

This application is a bypass continuation application of international application No. PCT/JP2024/014516 having an international filing date of Apr. 10, 2024 and designating the United States, the international application being based upon and claiming the benefit of priority from Japanese Patent Application No. 2023-067341, filed on Apr. 17, 2023. The entire contents of both of these applications are incorporated herein by reference.

### TECHNICAL FIELD

The present disclosure relates to an information processing apparatus, computer-readable medium, and an information processing method.

### BACKGROUND

PTL 1 discloses a plasma processing apparatus that calculates an amount of heat input from plasma and a thermal resistance between a processing object and a heater, and calculates a set temperature of the heater at which the processing object reaches a target temperature, using the calculated amount of heat input and the thermal resistance.

### CITATION LIST

### Patent Documents

PTL 1: JP2019-91880A

### SUMMARY

The present disclosure provides an information processing apparatus, computer-readable medium and an information processing method capable of determining an offset value with respect to a set temperature of a coolant in consideration of a thermal resistance peculiar to an apparatus and a heat flux different for each step of a process recipe.

A computer-readable medium according to an embodiment of the present disclosure includes computer-readable instructions that cause a computer to execute processing for a substrate processing apparatus including a substrate stage and a cooling base configured to cool the substrate stage with a coolant supplied from a cooling device. The process includes acquiring temperature data indicating a temperature of a substrate placed on the substrate stage and temperature data indicating a temperature of the cool ant, and calculating, based on the acquired temperature data indicating the temperature of the substrate and the acquired temperature data indicating the temperature of the coolant, a thermal resistance of a heat conduction site on a heat transfer path from the substrate to the coolant. The process also includes calculating a heat flux to the substrate for each of a plurality of steps of a process recipe defining a substrate processing to be performed on the substrate, and calculating, based on the calculated thermal resistance and the calculated heat flux, an offset value to be added to a set temperature of the coolant for each of the steps.

According to the present disclosure, an offset value with respect to a set temperature of a coolant can be determined in consideration of a thermal resistance peculiar to an apparatus and a heat flux different for each step of a process recipe.

### BRIEF DESCRIPTION OF DRAWINGS

FIG. 1 is a schematic diagram illustrating an example of a configuration example of a plasma processing system.

FIG. 2 is a diagram illustrating an adjustment mechanism of a substrate temperature.

FIG. 3 is a schematic diagram illustrating a configuration example of a thermal circuit model.

FIG. 4 is a flowchart illustrating a procedure of a process performed by a processor.

### DETAILED DESCRIPTION

Hereinafter, the invention will be specifically described based on the drawings illustrating an embodiment thereof.

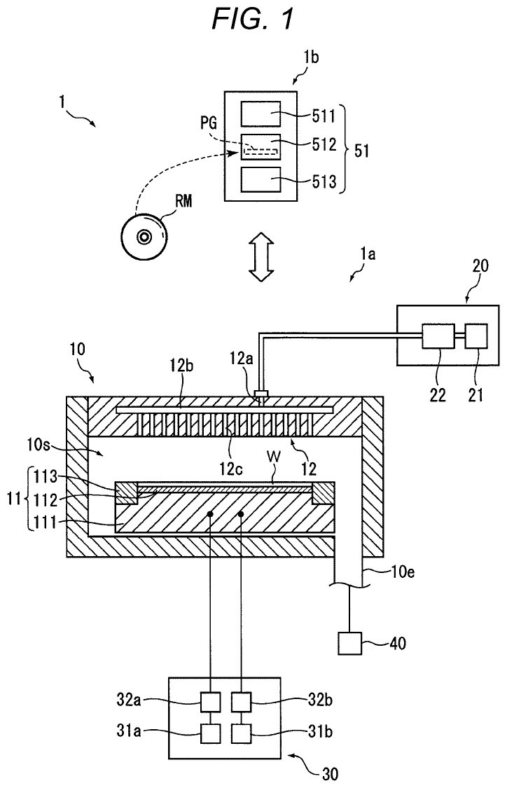

FIG. 1 is a schematic diagram illustrating an example of a configuration example of a plasma processing system 1. In an embodiment, the plasma processing system 1 includes a plasma processing apparatus 1a and a controller 1b. The plasma processing apparatus 1a includes a plasma processing chamber 10, a gas supply 20, a radio frequency (RF) power supply 30, and an exhaust system 40. The plasma processing apparatus 1a includes a support 11 and an upper-electrode shower head 12. The support 11 is disposed in a lower region of a plasma processing space 10s in the plasma processing chamber 10. The upper-electrode shower head 12 is disposed above the support 11 and may function as a part of a ceiling portion (ceiling) of the plasma processing chamber 10.

The support 11 is configured to support a substrate W in the plasma processing space 10s. In one embodiment, the support 11 includes a lower electrode 111, an electrostatic chuck 112, and an edge ring 113. The electrostatic chuck 112 is disposed on the lower electrode 111, and configured to support the substrate W on the upper surface thereof. The edge ring 113 is disposed to surround the substrate W on the upper surface of the peripheral edge of the lower electrode 111. Although not illustrated, in one embodiment, the support 11 may include a temperature control module configured to adjust at least one of the electrostatic chuck 112 and the substrate W to a target temperature. The temperature control module (temperature controller) may include a heater, a flow path, or a combination thereof. A temperature control fluid such as a coolant or a heat transfer gas flows through the flow path.

The upper-electrode shower head 12 is configured to supply one or more processing gases from the gas supply 20 into the plasma processing space 10s. In an embodiment, the upper-electrode shower head 12 includes a gas inlet 12a, a gas diffusion chamber 12b, and a plurality of gas outlets 12c. The gas inlet 12a is provided in fluid communication with the gas supply 20 and the gas diffusion chamber 12b. The plurality of gas outlets 12c are provided in fluid communication with the gas diffusion chamber 12b and the plasma processing space 10s. In an embodiment, the upper-electrode shower head 12 is configured to supply one or more processing gases from the gas inlet 12a into the plasma processing space 10s through the gas diffusion chamber 12b and the plurality of gas outlets 12c.

The gas supply 20 may include one or more gas sources 21 and one or more flow rate controllers 22. In an embodiment, the gas supply 20 is configured to supply one or more processing gases from their corresponding gas sources 21 to the gas inlet 12a through their corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of one or more processing gases.

The RF power supply 30 is a circuit configured to supply Radio Frequency (RF) power, for example, one or more RF signals to one or more electrodes such as the lower electrode 111, the upper-electrode shower head 12, or both the lower electrode 111 and the upper-electrode shower head 12. As a result, plasma is generated from one or more processing gases supplied into the plasma processing space 10s. Accordingly, the RF power supply 30 may function as at least a part of a plasma generator configured to generate plasma from one or more processing gases in the plasma processing chamber. In an embodiment, the RF power supply 30 includes two RF generators 31a and 31b and two matching circuits 32a and 32b. In one embodiment, the RF power supply 30 is configured to supply a first RF signal from the first RF generator 31a to the lower electrode 111 through the first matching circuit 32a. For example, the first RF signal may have a frequency within a range of 27 MHz to 100 MHz.

In one embodiment, the RF power supply 30 is configured to supply a second RF signal from the second RF generator 31b to the lower electrode 111 through the second matching circuit 32b. For example, the second RF signal may have a frequency within a range of 400 kHz to 13.56 MHz. Alternatively, a direct current (DC) pulse generator may be used instead of the second RF generator 31b.

Although it is not illustrated, other embodiments may be considered in the present disclosure. For example, in an alternative embodiment, the RF power supply 30 may be configured to supply the first RF signal from the RF generator to the lower electrode 111, supply the second RF signal from another RF generator to the lower electrode 111, and supply a third RF signal from still another RF generator to the lower electrode 111. Further, in other alternative embodiments, a DC voltage may be applied to the upper-electrode shower head 12.

Further, in various embodiments, amplitudes of one or more RF signals (that is, the first RF signal, the second RF signal, and the like) may be pulsated or modulated. The amplitude modulation may include pulsating the RF signal amplitude between an ON state and an OFF state, or between two or more different ON states.

The exhaust system 40 may be connected to, for example, an exhaust port 10e disposed at a bottom portion of the plasma processing chamber 10. The exhaust system 40 may include a pressure valve and a vacuum pump. The vacuum pump may include a turbo molecular pump, a roughing pump or a combination thereof.

In an embodiment, the controller 1b is a circuit that processes computer-executable instructions to cause the plasma processing apparatus 1a to perform various processes to be described in the present disclosure. The controller 1b may be configured to control the respective components of the plasma processing apparatus 1a to perform the various processes to be described herein below. In an embodiment, a portion of the controller 1b or the entire controller 1b may be included in the plasma processing apparatus 1a. The controller 1b may include, for example, a computer 51. For example, the computer 51 may include a processor (CPU: Central Processing Unit) 511, a storage (SU) 512, and a communication interface (CI) 513. The processor 511 may be configured to perform various control operations based on a program stored in the storage 512. The storage 512 may include a random access memory (RAM), a read only memory (ROM), a hard disk drive (HDD), a solid state drive (SSD), or a combination thereof. The communication interface 513 may communicate with the plasma processing apparatus 1a via a communication line such as a local area network (LAN).

The storage 512 may store various computer programs to be executed by the processor 511. The computer programs stored in the storage 512 include, for example, a computer program PG for causing the processor 511 to calculate a thermal resistance peculiar to an apparatus and a heat flux different for each step of a process recipe, and to perform a process of determining an offset value to be added to the set temperature of the coolant based on the calculated thermal resistance or the heat flux. The computer program PG is provided by a recording medium RM, such as a non-transitory computer-readable medium, or communication. The computer program PG may be a single computer program or may be a program group including a plurality of computer programs. In addition, the computer program PG may partially use an existing library.

In the present embodiment, the plasma processing apparatus 1a is an example of a substrate processing apparatus. The plasma processing apparatus 1a includes, for example, an etching apparatus, an ion implantation apparatus, a plasma chemical vapor deposition (CVD) apparatus, and an ashing apparatus. The substrate processing apparatus includes, for example, an exposure apparatus as an apparatus other than the plasma processing apparatus 1a.

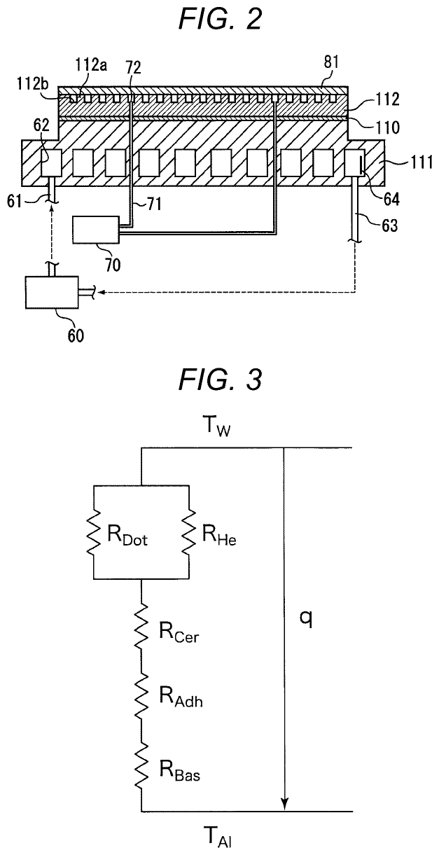

FIG. 2 is a diagram illustrating an adjustment mechanism of a substrate temperature. The support 11 of the plasma processing apparatus 1a includes the lower electrode 111 and the electrostatic chuck 112. In the present embodiment, the lower electrode 111 functions as a cooling base for cooling the electrostatic chuck 112, and the electrostatic chuck 112 functions as a substrate stage on which the substrate W to be processed is placed.

A coolant passage 62 is formed in the lower electrode 111. The coolant passage 62 is a continuous flow path, and one end thereof communicates with an inlet pipe 61 and the other end thereof communicates with an outlet pipe 63. A coolant is supplied from a chiller unit 60 provided outside the plasma processing chamber 10 to the coolant passage 62 through the inlet pipe 61. As the coolant, a medium such as brine is used. The temperature of the coolant is controlled by the chiller unit 60. The coolant supplied from the chiller unit 60 flows into the coolant passage 62 inside the lower electrode 111 through the inlet pipe 61, and flows back to the chiller unit 60 through the outlet pipe 63. A temperature sensor 64 is provided at one or more locations of the flow path through which the coolant flows. In the present example, the temperature sensor 64 is provided in the lower electrode 111. However, the temperature sensor 64 may be provided in the outlet pipe 63 outside the lower electrode 111. The temperature sensor 64 measures the temperature of the coolant at the installation location in time series, and outputs the obtained temperature data to the controller 1b.

A plurality of protruding portions 112a and recess portions 112b are provided on an upper surface of the electrostatic chuck 112. The radially protruding portion 112a has a tiny columnar shape that protrudes upward, and the substrate W to be processed is supported by an upper surface of the radially protruding portion 112a. In FIG. 2, in order to clearly show the shape of the protruding portion 112a, the protruding portion 112a is illustrated in an exaggerated manner compared to an actual size. A gas discharge port 72 is provided in a gap (recess portion 112b) formed between the substrate W and the electrostatic chuck 112. A gas supply line 71 is connected to the gas discharge port 72. The gas discharge port 72 discharges a heat transfer gas supplied from a gas supply mechanism 70 through the gas supply line 71 to the gap (the recess portion 112b) between the substrate W and the electrostatic chuck 112. In the present embodiment, the heat transfer gas is helium gas. Alternatively, the heat transfer gas may be another inert gas such as argon gas. The gas supply mechanism 70 includes a flow rate controller and a pressure controller, and controls a flow rate and a gas pressure of the heat transfer gas flowing into the recess portion 112b.

The plasma processing apparatus 1a can control the temperature of the substrate W placed on the electrostatic chuck 112 by controlling the temperature of the coolant supplied by the chiller unit 60 and the gas pressure of the heat transfer gas supplied by the gas supply mechanism 70. In the present embodiment, in order to observe a temperature change of the substrate W, a temperature measurement wafer 81 (hereinafter, referred to as a temperature measurement wafer 81) is used instead of the substrate W. The temperature measurement wafer 81 is, for example, a wafer with a thermocouple, or a wafer in which a measurement device such as a sensor or a memory is embedded. The temperature measurement wafer 81 may measure the temperature of a plurality of points on a wafer surface or may measure the temperature of a representative point.

The lower electrode 111 and the electrostatic chuck 112 are bonded to each other by an adhesive layer 110. As the material of the adhesive layer 110, an adhesive having high heat conduction can be used. When attention is paid to the function as the cooling base of the lower electrode 111, the adhesive layer 110 functions as a cooling layer interposed between the lower electrode 111 (the cooling base) and the electrostatic chuck 112 (the substrate stage). As the material of the adhesive layer 110, an adhesive having high electric resistance may be used so that the adhesive layer 110 has a function of electrically insulating the lower electrode 111 and the electrostatic chuck 112 from each other. As the adhesive having high heat conduction and electric resistance, for example, a silicone-based material, an acrylic material which is an acryl-based material or an acrylate-based material, or an organic-based adhesive containing a polyimide silica-based material can be used.

In such a plasma processing apparatus 1a, a heat transfer path from the substrate W to the coolant has thermal resistance, and thus the temperature of the substrate W and the temperature of the cooling base at a coolant interface generally do not coincide with each other. Therefore, in the related art, a relationship between the set temperature of the chiller unit 60 and the temperature of the substrate W is grasped in advance at an introduction destination (for example, device manufacturer) of the plasma processing apparatus 1a, and an offset value with respect to the set temperature of the chiller unit 60 is determined such that the temperature of the substrate W is a desired temperature.

However, individual differences (machine differences) are present in the plasma processing apparatus 1a. That is, the surface of the electrostatic chuck 112 is undulating and the shape of the protruding portions 112a varies, so that there is a machine difference in the thermal resistance on the surface of the electrostatic chuck 112 (thermal resistance of the protruding portions 112a). Since the thickness of the adhesive layer 110 also varies, there is also a machine difference in the thermal resistance of the adhesive layer 110.

In plasma processing (etching process) performed in the plasma processing apparatus 1a, which includes a plurality of steps under different conditions, the heat flux from the plasma to the substrate W varies from step to step in the process recipe.

Therefore, in order to calculate the offset value for eliminating the machine difference between the plasma processing apparatuses 1a by the device manufacturer under such a situation, it is necessary to perform a test for each apparatus and for each step of the process recipe, and it takes a large amount of man-hours to correct the set temperature.

In contrast, the present embodiment proposes a method in which the temperature of the substrate W in consideration of the heat flux from plasma different for each step of the process recipe can be easily corrected in a small number of man-hours by obtaining in advance the necessary thermal resistance and heat flux.

FIG. 3 is a schematic diagram illustrating a configuration example of a thermal circuit model. In the thermal circuit model shown in FIG. 3, T_{W} represents a temperature of the substrate W, and T_{Al} represents the temperature of the cooling base. The temperature sensor measures both the substrate temperature T_{W} and the base temperature T_{Al}. As the substrate temperature T_{W} and the base temperature T_{Al}, an average of temperatures measured at a plurality of points may be used as a representative (reference) value, or a temperature at any one point may be used as a representative (reference) value. The substrate temperature T_{W} may be a value reproduced by the temperature measurement wafer. R_{Dot} represents a thermal resistance of the protruding portion 112a provided on the surface of the electrostatic chuck 112, and R_{He} represents a thermal resistance of the heat transfer gas (helium gas) flowing through the recess portion 112b. The shape of the protruding portion 112a varies, and there is a machine difference in the thermal resistance R_{Dot}. In the thermal circuit model, the thermal resistance R_{Dot} is treated as a variable to be calculated. Meanwhile, since the thermal resistance R_{He} of the heat transfer gas (helium gas) flowing through the recess portion 112b can be theoretically calculated if a type, a flow rate, a pressure, and the like of the gas are known, the thermal resistance R_{He} is treated as a known value (constant) in the thermal circuit model.

R_{Cer} represents a thermal resistance of the electrostatic chuck 112 (excluding the protruding portion 112a and the recess portion 112b), R_{Adh} represents a thermal resistance of the adhesive layer 110, and R_{Bas} represents a thermal resistance of the cooling base (lower electrode 111). Since the thermal resistances R_{Cer} and R_{Bas} can be theoretically calculated if a material, a thickness, and the like are known, the thermal resistances R_{Cer} and R_{Bas} are treated as a known value (constant) in the thermal circuit model. On the other hand, since the thickness of the adhesive layer 110 varies, there is a machine difference in the thermal resistance R_{Adh}. In the thermal circuit model, the thermal resistance R_{Adh} is treated as a variable to be calculated.

The parameter q represents a heat flux from the plasma generated in the plasma processing chamber 10 to the substrate W. The heat flux q has a small machine difference and reproducibility, but since the heat flux changes for each step of the process recipe, it is treated as a variable in the thermal circuit model.

The following calculation formula is obtained from the thermal circuit model shown in FIG. 3. R_{ESC} included in the calculation formula is the thermal resistance of the entire heat transfer path from the substrate W to the coolant.

$${T}_{W} = q \times {R}_{ESC} + {T}_{COOLANT} \qquad [ Equation 1 ]$$

$${R}_{ESC} = \frac{{R}_{Dot} {R}_{He}}{{R}_{Dot} + {R}_{He}} + {R}_{Cer} + {R}_{Adh} + {R}_{Bas} \qquad [ Equation 2 ]$$

In Equations 1 and 2, variables to be calculated are the heat flux q from the plasma, the thermal resistance R_{Dot} of the protruding portion 112a, and the thermal resistance R_{Adh} of the adhesive layer 110.

The processor 511 included in the computer 51 calculates the heat flux q by a method described below, and calculates, using Equations 1 and 2, the thermal resistance R_{Dot} of the protruding portion 112a and the thermal resistance R_{Adh} of the adhesive layer 110.

The heat flux q included in Equation 1 can be obtained based on the temperature change of the coolant. An amount of heat Q_{OUT} exhausted through the coolant is represented by Q_{OUT}=(specific heat of coolant)×(flow rate of coolant)×(temperature increase of coolant). Here, the specific heat of the coolant is known, and the flow rate of the coolant is given as a set value. The temperature increase of the coolant is calculated based on temperature data output from the temperature sensor 64. The heat flux q is calculated by dividing Q_{OUT} by a sum of the area of the substrate W and the area of the edge ring 113.

When the heat flux q is obtained, only the thermal resistances R_{Dot} and R_{Adh} are unknown in Equations 1 and 2. Next, the processor 511 controls the plasma processing apparatus 1a with the controller 1b to vary a gas pressure of the heat transfer gas flowing into the recess portion 112b between at least two levels to obtain a saturation temperature of the substrate W. Accordingly, two or more equations can be obtained for the two unknowns. When two equations are obtained for two unknowns, the processor 511 obtains two unknowns (thermal resistance R_{Dot} and thermal resistance R_{Adh}) by solving these equations. When three or more equations are obtained for the two unknowns, the processor 511 numerically obtains a solution of the above-described equations (thermal resistance R_{Dot} and thermal resistance R_{Adh}) using a known method such as the least squares method.

The calculated values of the thermal resistance R_{Dot} and the thermal resistance R_{Adh} are constant regardless of the steps of the process recipe. However, the heat flux q varies according to the steps of the process recipe. Therefore, the processor 511 calculates the heat flux q for each of steps of the process recipe. The method for calculating the heat flux q is the same as that described above, and can be obtained based on the temperature change of the coolant.

The processor 511 obtains a value of the offset value/q using the following Equation 3.

$$[ Equation 3 ]$$

$$offset / q ≡ ( {T}_{COOLANT}^{′} - {T}_{COOLANT} ) / q = \frac{{R}_{Dot} {R}_{He}}{{R}_{Dot} + {R}_{He}} + {R}_{Adh} - \frac{{R}_{Dot}^{′} {R}_{He}}{{R}_{Dot}^{′} + {R}_{He}} - {R}_{Adh}^{′}$$

Here, the offset value is a value to be added to the set temperature of the coolant. Variables with a dash on the right side indicate values for the ESC under investigation, while variables without a dash indicate values for the standard ESC. T_coolant (T′_coolant) is the temperature of the coolant. As the variables without a dash including the T_coolant, a value to be used when a preferable etching result is obtained in the standard ESC is used. The thermal resistance R_{Dot} and the thermal resistance R_{Adh} are calculated using Equations 1 and 2 described above, and R_{He} is given as a known value (constant).

The processor 511 can calculate the heat flux for each step of the process recipe by using Equations 1 to 3, and can calculate an offset value corresponding thereto.

Hereinafter, a procedure of the process to be performed by the processor 511 will be described.

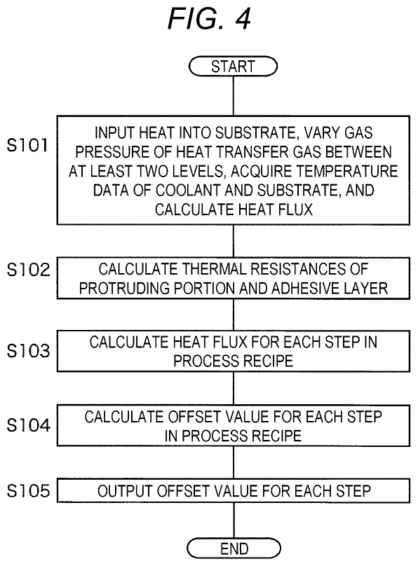

FIG. 4 is a flowchart illustrating a procedure of the process to be performed by the processor 511. The processor 511 performs the following processes by reading and executing the computer program PG from the storage 512 at the time of a shipment inspection of the apparatus or at the time of start-up of the apparatus by a device manufacturer. However, the processes of steps S101 and S102 for determining the thermal resistance may be performed by an electrostatic chuck manufacturer at the time of shipment of the electrostatic chuck 112.

The processor 511 controls the plasma processing apparatus 1a through the communication interface 513 to input heat into the substrate W, vary the gas pressure of the heat transfer gas between at least two levels, acquire temperature data of the coolant measured by the temperature sensor 64, and temperature data of the substrate W measured by the temperature measurement wafer 81, and calculate the heat flux q (step S101).

The heat flux q is calculated based on the temperature change of the coolant. An amount of heat Q_{OUT} exhausted through the coolant is represented by Q_{OUT}=(specific heat of coolant)×(flow rate of coolant)×(temperature increase of coolant). Here, the specific heat of the coolant is known, and the flow rate of the coolant is given as a set value. The processor 511 calculates the temperature increase of the coolant based on the temperature data output from the temperature sensor 64, and substitutes the calculated value into the above calculation formula to calculate the amount of heat Q_{OUT}. The processor 511 calculates the heat flux q by dividing the calculated amount of heat Q_{OUT} by the sum of the area of the substrate W and the area of the edge ring 113.

Next, the processor 511 calculates the thermal resistance R_{Dot} of the protruding portion 112a of the electrostatic chuck 112 and the thermal resistance R_{Adh} of the adhesive layer 110 (step S102). Specifically, the processor 511 can calculate the thermal resistance R_{Dot} and the thermal resistance R_{Adh} by using Equations 1 and 2. The heat flux q necessary for the calculation of Equation 1 is obtained from step S101. In order to calculate the two variables (the thermal resistance R_{Dot} and the thermal resistance R_{Adh}), the processor 511 controls the plasma processing apparatus 1a to vary the gas pressure of the heat transfer gas flowing through the recess portion 112b between at least two levels to obtain the saturation temperature of the substrate W, thereby generating at least two equations for the two unknowns. When two equations are obtained for two unknowns, the processor 511 obtains two unknowns (thermal resistance R_{Dot} and thermal resistance R_{Adh}) by solving these equations. When three or more equations are obtained for the two unknowns, the processor 511 calculates the thermal resistance R_{Dot} and the thermal resistance R_{Adh} by performing numerical calculations using a known method such as the least squares method.

Next, the processor 511 obtains the heat flux q for each step of the process recipe (step S103), and calculates an offset value for each step of the process recipe (step S104). The processor 511 calculates an offset value to be added to the set temperature of the coolant by using Equation 3.

Next, the processor 511 outputs an offset value for each step (step S105). For example, the processor 511 generates a table in which step numbers of each of steps and the offset values obtained for each of steps are associated with each other, and transmits the generated table to a user terminal through the communication interface 513. When the computer 51 includes a display such as a liquid crystal display, the table may be displayed on the display. Alternatively, the processor 511 may set the calculated offset value for each of steps to the process recipe used by the plasma processing apparatus 1a that is a control target, and control the plasma processing (etching process) performed by the plasma processing apparatus 1a.

As described above, in the embodiment, by obtaining not the substrate temperature which is a final output but the thermal resistance and the heat flux which cause the final output in advance, the substrate temperature can be corrected with a small number of man-hours for the heat flux from the plasma which is different for each step of the process recipe.

The embodiments disclosed herein are exemplary in all respects and are required to be considered to be not restrictive embodiments. The scope of the present invention is indicated by the scope of the aspects, not the meaning described above, and is intended to include meanings equivalent to the scope of the aspects and all changes within the scope.

The features described in each embodiment can be combined with each other. In addition, the independent and dependent claims set forth in the claims can be combined with each other in any and all combinations, regardless of the reciting format.

1. A non-transitory computer-readable medium storing a computer program that causes a computer to execute a process for a substrate processing apparatus including a substrate stage and a cooling base configured to cool the substrate stage with a coolant supplied from a cooling device, the process comprising:
acquiring temperature data indicating a temperature of a substrate placed on the substrate stage and temperature data indicating a temperature of the coolant;
calculating, based on the acquired temperature data indicating the temperature of the substrate and the acquired temperature data indicating the temperature of the coolant, a thermal resistance of a heat conduction site on a heat transfer path from the substrate to the coolant;
calculating a heat flux to the substrate for each of a plurality of steps of a process recipe defining a substrate processing to be performed on the substrate; and
calculating, based on the calculated thermal resistance and the calculated heat flux, an offset value to be added to a set temperature of the coolant for each of the steps.

2. The non-transitory computer-readable medium according to claim 1, further comprising:
calculating the thermal resistance and the heat flux using a thermal circuit model configured to simulate a thermal phenomenon in the heat transfer path.

3. The non-transitory computer-readable medium according to claim 2, wherein
a plurality of protruding portions on which a substrates is to be placed are formed on a surface of the substrate stage, and
the thermal circuit model includes a thermal resistance of the protruding portions as a variable.

4. The non-transitory computer-readable medium according to claim 2, wherein
the substrate stage and the cooling base are bonded to each other through an adhesive layer, and
the thermal circuit model includes a thermal resistance in the adhesive layer as a variable.

5. The non-transitory computer-readable medium according to claim 2, further comprising:
numerically calculating the thermal resistance using a plurality of equations obtained from the thermal circuit model by changing a saturation temperature of the substrate.

6. The non-transitory computer-readable medium according to claim 1, further comprising:
calculating the heat flux for each of the steps of the process recipe based on a temperature change of the coolant.

7. The non-transitory computer-readable medium computer program according to claim 3, further comprising:
numerically calculating the thermal resistance using a plurality of equations obtained from the thermal circuit model by changing a saturation temperature of the substrate.

8. The non-transitory computer-readable medium computer program according to claim 4, further comprising:
numerically calculating the thermal resistance using a plurality of equations obtained from the thermal circuit model by changing a saturation temperature of the substrate.

9. An information processing apparatus comprising:
a processor circuit; and
a communication circuit, wherein
the communication circuit is configured to acquire, for a substrate processing apparatus including a substrate stage and a cooling base configured to cool the substrate stage with a coolant supplied from a cooling device, temperature data indicating a temperature of a substrate placed on the substrate stage and temperature data indicating a temperature of the coolant, and
the processor circuit is configured to
calculate, based on the acquired temperature data indicating the temperature of the substrate and the acquired temperature data indicating the temperature of the coolant, a thermal resistance of a heat conduction site on a heat transfer path from the substrate to the coolant,
calculate a heat flux to the substrate for each of a plurality of steps of a process recipe defining a substrate processing to be performed on the substrate, and
calculate, based on the calculated thermal resistance and the calculated heat flux, an offset value to be added to a set temperature of the coolant for each of the steps.

10. The information processing apparatus according to claim 9, wherein the processor circuit is further configured to:
calculate the thermal resistance and the heat flux using a thermal circuit model configured to simulate a thermal phenomenon in the heat transfer path.

11. The information processing apparatus according to claim 10, wherein
a plurality of protruding portions on which a substrates is to be placed are formed on a surface of the substrate stage, and
the thermal circuit model includes a thermal resistance of the protruding portions as a variable.

12. The information processing apparatus according to claim 10, wherein
the substrate stage and the cooling base are bonded to each other through an adhesive layer, and
the thermal circuit model includes a thermal resistance in the adhesive layer as a variable.

13. The information processing apparatus according to claim 10, wherein the processor circuit is further configured to:
numerically calculate the thermal resistance using a plurality of equations obtained from the thermal circuit model by changing a saturation temperature of the substrate.

14. The information processing apparatus according to claim 9, wherein the processor circuit is further configured to:
calculate the heat flux for each of the steps of the process recipe based on a temperature change of the coolant.

15. An information processing method for causing a computer to execute processing for a substrate processing apparatus including a substrate stage and a cooling base configured to cool the substrate stage with a coolant supplied from a cooling device, the method comprising:
acquiring temperature data indicating a temperature of a substrate placed on the substrate stage and temperature data indicating a temperature of the coolant;
calculating, based on the acquired temperature data indicating the temperature of the substrate and the acquired temperature data indicating the temperature of the coolant, a thermal resistance of a heat conduction site on a heat transfer path from the substrate to the coolant;
calculating a heat flux to the substrate for each of a plurality of steps of a process recipe defining a substrate processing to be performed on the substrate; and
calculating, based on the calculated thermal resistance and the calculated heat flux, an offset value to be added to a set temperature of the coolant for each of the steps.

16. The information processing method according to claim 15, further comprising:
calculating the thermal resistance and the heat flux using a thermal circuit model configured to simulate a thermal phenomenon in the heat transfer path.

17. The information processing method according to claim 16, wherein
a plurality of protruding portions on which a substrates is to be placed are formed on a surface of the substrate stage, and
the thermal circuit model includes a thermal resistance of the protruding portions as a variable.

18. The information processing method according to claim 16, wherein
the substrate stage and the cooling base are bonded to each other through an adhesive layer, and
the thermal circuit model includes a thermal resistance in the adhesive layer as a variable.

19. The information processing method according to claim 16, further comprising:
numerically calculating the thermal resistance using a plurality of equations obtained from the thermal circuit model by changing a saturation temperature of the substrate.

20. The information processing method according to claim 15, further comprising:
calculating the heat flux for each of the steps of the process recipe based on a temperature change of the coolant.
